(19) United States
(12) Patent Application Publication
(10) Pub. No.: US 2025/0228109 A1
(43) Pub. Date: Jul. 10, 2025

(54) DISPLAY DEVICE

(71) Applicant: Samsung Display Co., LTD., Yongin-si (KR)

(72) Inventors: DONG GYU BAECK, Yongin-si (KR); MINSEOK KIM, Yongin-si (KR); SONG YI KIM, Yongin-si (KR); Su Jin KIM, Yongin-si (KR); YONGSEOK CHOI, Yongin-si (KR)

(21) Appl. No.: 18/806,927

(22) Filed: Aug. 16, 2024

(30) Foreign Application Priority Data
Jan. 4, 2024 (KR) 10-2024-0001437

(51) Int. Cl. H10K 59/80; H10K 59/122; H10K 59/38

(52) U.S. Cl. CPC H10K 59/877; H10K 59/122; H10K 59/38

(57) ABSTRACT

A display device includes a first substrate, a transistor disposed on the first substrate, a light emitting element electrically connected to the transistor, a partition wall disposed on the light emitting element with an opening defined therethrough, and a color conversion layer disposed within the opening and including quantum dots, where the color conversion layer includes a first sub-region adjacent to the partition wall and containing a first scatterer, and a second sub-region overlapping a center of the color conversion layer in a plan view and including a second scatterer, and one of the first and second scatterers is rutile, and the other of the first and second scatterers is anatase.

This application claims priority to Korean Patent Application No. 10-2024-0001437, filed on Jan. 4, 2024, and all the benefits accruing therefrom under 35 U.S.C. § 119, the content of which in its entirety is herein incorporated by reference.

### BACKGROUND

### (1) Field

This disclosure relates to a display device.

### (2) Description of the Related Art

A light emitting element is a device that forms an exciton by combining holes supplied from an anode and electrons supplied from a cathode within a light emitting layer formed between the anode and cathode, and emits light as this exciton stabilizes.

Light emitting elements have various desired characteristics such as wide viewing angle, fast response speed, thinness, and low power consumption, so such light emitting elements are widely applied to various electrical and electronic devices such as televisions, monitors, and mobile phones.

Recently, a display device including a color conversion layer has been proposed to implement a highly efficient display device.

The color conversion layer may convert incident light into a different color.

### SUMMARY

Embodiments are intended to provide a display device with improved front light efficiency.

A display device according to an embodiment includes a first substrate, a transistor disposed on the first substrate, a light emitting element electrically connected to the transistor, a bank disposed on the light emitting element, where an opening is defined through the bank, and a color conversion layer disposed within the opening, where the color conversion layer includes quantum dots, where the color conversion layer includes a first sub-region adjacent to the bank and including a first scatterer, and a second sub-region overlapping a center of the color conversion layer in a plan view and including a second scatterer, where one of the first scatterer and the second scatterer is rutile and the other of the first scatterer and the second scatterer is anatase.

In an embodiment, the first scatterer may be rutile, and the second scatterer may be anatase.

In an embodiment, the first sub-region may include no quantum dot, and the second sub-region may include the quantum dots.

In an embodiment, the display device may further include a transmission layer disposed within another opening defined through the bank, and the transmission layer may include the first scatterer.

In an embodiment, the color conversion layer may be a second color conversion layer, and the display device may further include a first color conversion layer disposed within another opening defined through the bank, and the first color conversion layer may include the first scatterer.

In an embodiment, the second sub-region may be disposed between the first sub-region and the bank in the plan view.

In an embodiment, the light emitting element may emit light which is a mixture of green light and blue light.

In an embodiment, each of the first scatterers and the second scatterers may have a diameter in a range of about 20 nanometers (nm) to about 500 nm.

In an embodiment, each of the first sub-region and the second sub-region may include the quantum dot.

In an embodiment, the transmission layer may include a third sub-region including the first scatterer and a fourth sub-region including the second scatterer.

In an embodiment, the display device may further include an encapsulation layer disposed on the light emitting element, a second substrate disposed opposite to the first substrate, a color filter disposed between the second substrate and the encapsulation layer, a color filter between the color filter and the encapsulation layer, and a filling layer disposed between the color filter and the encapsulation layer, and the bank and the color conversion layer may be disposed between the color filter and the filling layer.

In an embodiment, the display device may further include an encapsulation layer disposed on the light emitting element, a second substrate disposed opposite to the first substrate, a color filter disposed between the second substrate and the encapsulation layer, a color filter between the color filter and the encapsulation layer, and a filling layer disposed between the color filter and the encapsulation layer, and the bank and the color conversion layer may be disposed between the encapsulation layer and the filling layer.

A display device according to an embodiment includes a first substrate, a transistor disposed on the first substrate, a light emitting element electrically connected to the transistor, a bank disposed on the light emitting element, where an opening is defined through the bank, and a color conversion layer disposed within the opening, where the color conversion layer includes quantum dots, where the color conversion layer includes a first sub-region adjacent to the bank and including a first scatterer, and a second sub-region overlapping a center of the color conversion layer in a plan view and including a second scatterer, and the first scatterer and the second scatterer are composed of a same type of atoms and have different crystal structures from each other.

In an embodiment, the first scatterer and the second scatterer may be TiO₂.

In an embodiment, one of the first scatterer and the second scatterer may be rutile, and the other of the first scatterer and the second scatterer may be anatase.

In an embodiment, the first scatterer may be rutile, and the second scatterer may be anatase.

In an embodiment, the first sub-region may include no quantum dot, and the second sub-region may include the quantum dots.

In an embodiment, the display device may further include a transmission layer disposed within another opening defined through the bank, and the transmission layer may include the first scatterer.

In an embodiment, the color conversion layer may be a second color conversion layer, and the display device may further include a first color conversion layer disposed within another opening defined through the bank, and the first color conversion layer may include the first scatterer.

In an embodiment, the light emitting element may emit light which is a mixture of green light and blue light.

According to embodiments, the display device may have improved front emission efficiency.

### BRIEF DESCRIPTION OF THE DRAWINGS

FIG. 1 is a schematic exploded perspective view of a display device according to an embodiment.

FIG. 2 is a schematic cross-sectional view of a display panel according to an embodiment.

FIG. 3 is a cross-sectional view of a display panel according to an embodiment.

FIG. 4 is a diagram showing the crystal form of a scatterer according to an embodiment.

FIG. 5 is a diagram showing the form of light emitted from the second color conversion layer according to an embodiment.

FIGS. 6 and 7 are diagrams of a method for manufacturing a second color conversion layer according to an embodiment.

FIGS. 8, 9, and 10 are cross-sectional views of a display panel according to other embodiments.

FIG. 11 is an image of a second color conversion layer according to an inkjet process according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In order to clearly explain the invention, parts that are not relevant to the description are omitted, and identical or similar components are assigned the same reference numerals throughout the specification.

In addition, the size and thickness of each component shown in the drawings are shown arbitrarily for convenience of explanation, so the invention is not necessarily limited to that which is shown.

In the drawing, the thickness is enlarged to clearly express various layers and areas.

And in the drawings, for convenience of explanation, the thicknesses of some layers and regions are exaggerated.

Additionally, when a part of a layer, membrane, region, or plate is said to be “above” or “on” another part, this includes not only cases where it is “directly above” another part, but also cases where there is another part in between.

In contrast, when an element is referred to as being “directly on” another element, there are no intervening elements present.

In addition, being “above” or “on” a reference part means being disposed above or below the reference part, and does not necessarily mean being disposed “above” or “on” it in the direction opposite to gravity.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

In addition, throughout the specification, when reference is made to “on a plane,” this means when the target portion is viewed from above, and when reference is made to “in a cross-section,” this means when a cross-section of the target portion is cut vertically and viewed from the side.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

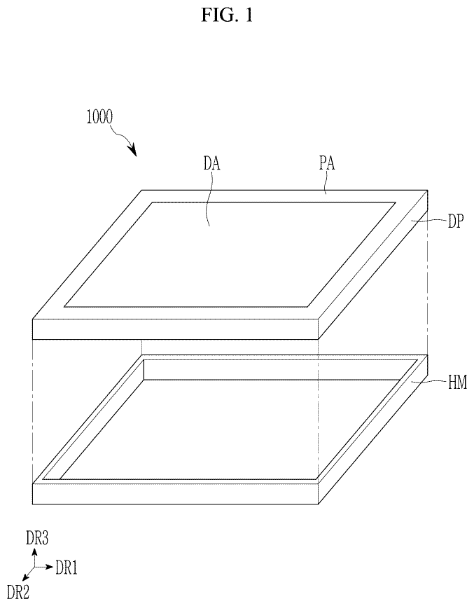

Hereinafter, a display device according to an embodiment will be described with reference to FIG. 1.

FIG. 1 is a schematic exploded perspective view of a display device according to an embodiment.

Referring to FIG. 1, a display device 1000 according to an embodiment may include a display panel DP and a housing HM.

A side of the display panel DP on which the image is displayed is parallel to the side defined by a first direction DR1 a the second direction DR2.

A third direction DR3 indicates a normal direction of one side, on which the image is displayed, that is, the thickness direction of the display panel DP.

The front (or upper) and back (or lower) surfaces of each member are separated by the third direction DR3 or opposite to each other in the third direction DR3.

However, the directions indicated by the first to third directions DR1, DR2, and DR3 are relative concepts and may be converted to other directions.

The display panel DP may be a flat rigid display panel, but is not limited thereto and may be a flexible display panel.

In an embodiment, the display panel DP may be an organic light emitting display panel.

However, the type of display panel DP is not limited to this and may be one of other various types of display panel.

In an embodiment, for example, the display panel DP may be a liquid crystal display panel, an electrophoretic display panel or an electrowetting display panel, etc.

Additionally, the display panel DP may be a next-generation display panel such as a micro light emitting diode (LED) display panel, a quantum dot LED display panel, or a quantum dot organic light emitting diode display panel.

Micro LED display panels may be defined as panels including LEDs having a size (e.g., a width or length) in a range of about 10 micrometers to about 100 micrometers to form each pixel.

Such micro LED display panels may be desired because the micro LED display panels use inorganic materials, do not include a backlight, the response speed of the micro LED display panels is fast, high brightness may be achieved with low power by the micro LED display panels, and the micro LED display panels may not break when bent.

Quantum dot LED display panels may be formed by attaching a film including quantum dots or by using a material including quantum dots.

Quantum dots are particles including or made of inorganic materials such as indium and cadmium, emit light on their own, and have a diameter of several nanometers or less.

By controlling the particle size of quantum dots, light of a desired color may be displayed.

The quantum dot organic light emitting diode display panel uses a blue organic light emitting diode as a light source and displays color by attaching a film containing red and green quantum dots on it or depositing a material containing red and green quantum dots.

The display panel DP according to an embodiment may be any one of other various types of display panel.

In an embodiment, as shown in FIG. 1, the display panel DP includes a display area DA where an image is displayed, and a non-display area PA adjacent to the display area DA.

The non-display area PA is an area where images are not displayed, that is, no pixel is disposed.

In an embodiment, for example, the display area DA may have a square shape, and the non-display area PA may have a shape surrounding the display area DA.

However, the shape of the display area DA and the non-display area PA may be variously modified without being limited thereto.

The housing HM provides a predetermined internal space.

The display panel DP is mounted inside the housing HM, or disposed in the predetermined internal space of the housing HM.

In addition to the display panel DP, various electronic components, such as a power supply unit, a storage device, and an audio input/output module, may be mounted inside the housing HM.

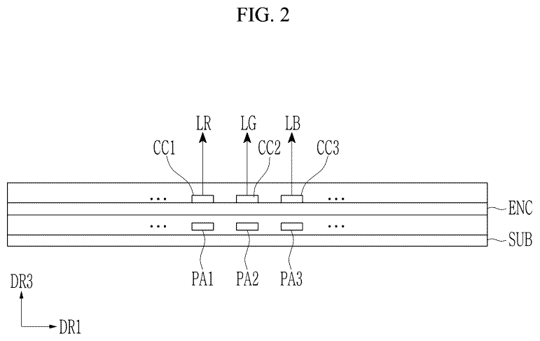

Hereinafter, the display area of the display panel according to an embodiment will be described with reference to FIG. 2.

FIG. 2 is a schematic cross-sectional view of a display panel according to an embodiment.

Referring to FIG. 2, a plurality of pixels PA1, PA2, and PA3 may be disposed on a substrate SUB corresponding to the display area DA of FIG. 1. Each pixel PA1, PA2, PA3 may include a plurality of transistors and a light emitting element connected thereto.

In this specification, the shape and arrangement of the plurality of pixels PA1, PA2, PA3 may be modified in various ways.

An encapsulation layer ENC may be disposed on the plurality of pixels PA1, PA2, PA3.

The display area DA may be protected from external air or moisture by the encapsulation layer ENC.

The encapsulation layer ENC may be integrally or commonly provided to overlap the entire surface of the display area DA, and may be partially disposed on the non-display area PA.

A first color conversion unit CC1, a second color conversion unit CC2, and a transmission unit CC3 may be disposed on the encapsulation layer ENC.

The first color conversion unit CC1 overlaps the first pixel PA1 in the third direction DR3 (i.e., a thickness direction of the substrate SUB), the second color conversion unit CC2 overlaps the second pixel PA2 PA1 in the third direction DR3, and the transmission unit CC3 overlaps the third pixel PA3 PA1 in the third direction DR3.

Light emitted from the first pixel PA1 may pass through the first color conversion unit CC1 to provide red light LR.

Light emitted from the second pixel PA2 may pass through the second color conversion unit CC2 to provide green light LG.

Light emitted from the third pixel PA3 may pass through the transmission part CC3 to provide blue light LB.

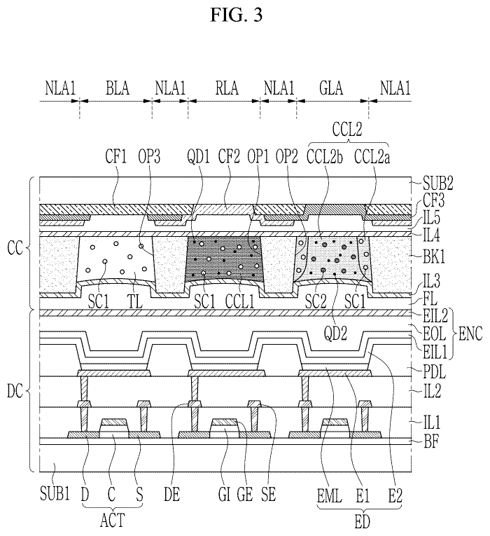

Hereinafter, the structure of the display panel according to an embodiment will be described at in more detail with reference to FIGS. 3 to 7.

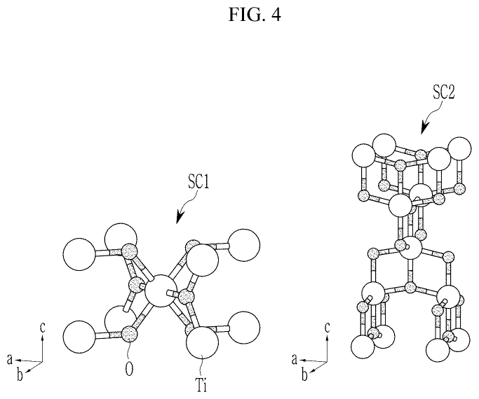

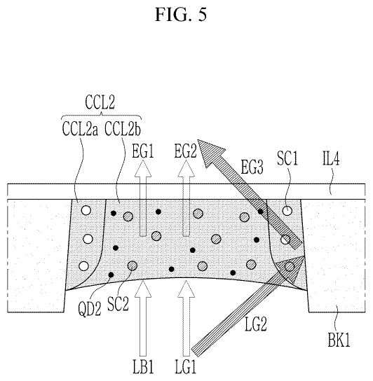

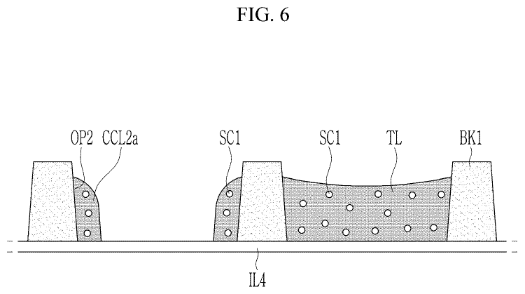

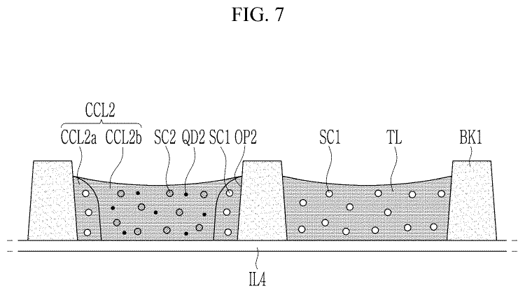

FIG. 3 is a cross-sectional view of a display panel according to an embodiment, FIG. 4 is a view showing the crystal form of a scatterer according to an embodiment, and FIG. 5 is a view showing the shape of light emitted from the second color conversion layer according to an embodiment, and FIGS. 6 and 7 are drawings showing a method of manufacturing a second color conversion layer according to an embodiment.

First, referring to FIG. 3, the display area DA according to an embodiment includes a red light emission area RLA, a green light emission area GLA, and a blue light emission area BLA.

A non-emission area NLA1 may be disposed (or defined) between the red light emission area RLA, the green light emission area GLA, and the blue light emission area BLA.

Each light emitting area may correspond to a pixel.

In an embodiment, for example, the blue light emitting area BLA, red light emitting area RLA, and green light emitting area GLA may correspond to a blue pixel, a red pixel, and a green pixel, respectively.

Hereinafter, the cross-sectional structure of the display area DA will be described in detail.

The display unit DC according to an embodiment includes a first substrate SUB1.

The first substrate SUB1 may include a flexible material such as plastic that may be bent, folded, or rolled.

The buffer layer BF may be disposed on the first substrate SUB1.

In another embodiment, the buffer layer BF may be omitted.

The buffer layer BF may include a silicon nitride (SiNₓ), a silicon oxide (SiOₓ), or a silicon oxynitride (SiOₓN_{y}).

The buffer layer BF is disposed between the first substrate SUB1 and the semiconductor layer ACT, and improves the properties of polycrystalline silicon by blocking impurities from the first substrate SUB1 during the crystallization process to form polycrystalline silicon. The buffer layer BF may provide a flat surface on the first substrate SUB1, such that the stress of the semiconductor layer ACT provided or formed on the buffer layer BF may be alleviated.

A semiconductor layer ACT is disposed on the buffer layer BF.

The semiconductor layer ACT may include or be made of polycrystalline silicon or an oxide semiconductor.

The semiconductor layer ACT includes a channel region C, a source region S, and a drain region D.

The source region S and drain region D are respectively arranged on both opposing sides of the channel region C.

The channel region C is an intrinsic semiconductor that is not doped with impurities, and the source region S and drain region D are impurity semiconductors that are doped with conductive impurities.

In an embodiment, the semiconductor layer ACT may include or be made of an oxide semiconductor. In such an embodiment, a separate protective layer (not shown) may be added to protect the oxide semiconductor material, which is vulnerable to external environments such as high temperature.

A gate insulating layer GI is disposed on the semiconductor layer ACT.

The gate insulating layer GI may have a single layer structure or a multilayer structure, each layer therein including at least one selected from a silicon nitride (SiNₓ), a silicon oxide (SiOₓ), and a silicon oxynitride (SiOₓN_{y}).

A gate electrode GE is disposed on the gate insulating layer GI, the gate electrode GE includes at least one selected from copper (Cu), a copper alloy, aluminum (Al), an aluminum alloy, molybdenum (Mo), and a molybdenum alloy, and the gate electrode GE may have a multilayer structure in which metal layers are stacked.

An interlayer insulating layer IL1 is disposed on the gate electrode GE and the gate insulating layer GI.

The interlayer insulating layer IL1 may include a silicon nitride (SiNₓ), a silicon oxide (SiOₓ), or a silicon oxynitride (SiOₓN_{y}).

Openings exposing the source region S and the drain region D are defined or formed in the interlayer insulating layer IL1.

A source electrode SE and a drain electrode DE are disposed on the interlayer insulating layer IL1.

The source electrode SE and drain electrode DE are respectively connected to the source region S and drain region D of the semiconductor layer ACT through an opening defined or formed in the interlayer insulating layer IL1.

A protective layer IL2 is disposed on the interlayer insulating layer IL1, the source electrode SE, and the drain electrode DE.

The protective layer IL2 covers and flattens (or provides a flat surface on) the interlayer insulating layer IL1, the source electrode SE, and the drain electrode DE, so that the first electrode E1 may be formed on the protective layer IL2 without steps.

This protective layer IL2 may include or be made of an organic material such as polyacrylate resin or polyimide resin, or a laminated layer of an organic material and an inorganic material.

The first electrode E1 is disposed on the protective layer IL2.

The first electrode E1 is connected to the drain electrode DE through an opening defined or formed in the protective layer IL2.

A driving transistor comprising a gate electrode GE, a semiconductor layer ACT, a source electrode SE, and a drain electrode DE is connected to the first electrode E1 to supply a driving current to the light emitting element ED.

In addition to the driving transistor shown in FIG. 3, the display device according to an embodiment may further include a switching transistor (not shown) connected to a data line to transmit a data voltage in response to a scan signal, and a switching transistor (not shown) connected to the driving transistor and driven in response to the scan signal, and the display device may further include a compensation transistor (not shown) that compensates for the threshold voltage of a transistor.

A pixel defining layer PDL is disposed on the protective layer IL2 and the first electrode E1, and the pixel defining layer PDL may define a pixel opening that exposes a portion of the first electrode E1 corresponding to a light emitting area.

The pixel defining layer PDL may include an organic material such as polyacrylate resin or polyimide resin, or a silica-based inorganic material.

The pixel opening may have a planar shape substantially similar to that of the first electrode E1, and may have a diamond or octagonal shape similar to a diamond in a plan view (or when viewed in the thickness direction of the first substrate SUB1), but is not limited thereto and may have any other shape such as a square or polygon.

The light emitting layer EML is disposed on a portion of the first electrode E1 overlapping or exposed through the pixel opening.

The light emitting layer EML may include or be made of a low-molecular organic material or a high-molecular organic material such as poly(3,4-ethylenedioxythiophene) (PEDOT).

In addition, the light emitting layer EML includes a hole injection layer, a hole transporting layer, an electron transporting layer, and an electron injection layer, and light emitting layer EML may have a multilayer structure including one or more layers in addition to the layers described above.

In an embodiment, the emitting layer EML may be disposed mostly within the pixel opening, and may also be disposed on a side or on the pixel defining layer PDL.

The second electrode E2 is disposed on the light emitting layer EML.

The second electrode E2 may be disposed across a plurality of pixels and may receive a common voltage through a common voltage transmitter (not shown) in the non-display area.

The first electrode E1, the light emitting layer EML, and the second electrode E2 may form or collectively define a light emitting element ED.

In an embodiment, for example, the first electrode E1 may be an anode, which is a hole injection electrode, and the second electrode E2 may be a cathode, which is an electron injection electrode.

However, the embodiment is not necessarily limited to this, and alternatively, the first electrode E1 may be a cathode and the second electrode E2 may be an anode depending on the driving method of the organic light emitting display device.

Holes and electrons are injected into the light emitting layer EML from the first electrode E1 and the second electrode E2, respectively, and light emission occurs when excitons which are combinations of the injected holes and electrons falls from the excited state to the ground state.

The light emitting element ED according to an embodiment may include a plurality of light emitting units.

Each light emitting unit may include a light emitting layer.

The light emitting element ED may be a tandem structure light emitting element.

A plurality of light emitting layers may emit light of a same color as each other or light of different colors from each other.

In an embodiment, for example, the light emitting element ED may emit light that is a mixture of green light and blue light, or may emit blue light.

An encapsulation layer ENC is disposed on the second electrode E2.

The encapsulation layer ENC may seal the display layer by covering not only the top surface but also the side surfaces of the display layer including the light emitting element ED.

In an embodiment where the light emitting element is vulnerable to moisture and oxygen, the encapsulation layer ENC seals the display layer and blocks the inflow of external moisture and oxygen.

The encapsulation layer ENC may include a plurality of layers, and may be formed as or defined by a composite layer including both an inorganic layer and an organic layer, for example, including a first inorganic layer EIL1, an organic layer EOL, and a second inorganic layer.

The color conversion unit CC is disposed on the encapsulation layer ENC.

The color conversion unit CC includes a second substrate SUB2 that overlaps or disposed opposite to the first substrate SUB1.

The second substrate SUB2 may include a flexible material such as plastic that may bend, fold, or roll easily.

The color conversion unit CC includes a first color filter CF1, a second color filter CF2, and a third color filter CF3 disposed between the second substrate SUB2 and the display unit DC.

The first color filter CF1 may overlap a transmission layer TL.

The first color filter CF1 may transmit blue light that has passed through the transmission layer TL and is incident thereon (i.e., blue light incident thereon after passing through the transmission layer TL) and absorb light of the remaining wavelengths, thereby increasing the purity of blue light emitted to the outside of the display device.

The second color filter CF2 may overlap the first color conversion layer CCL1.

The second color filter CF2 may transmit red light that has passed through the first color conversion layer CCL1 and is incident thereon and absorb light of the remaining wavelengths, thereby increasing the purity of red light emitted to the outside of the display device.

The third color filter CF3 may overlap the second color conversion layer CCL2.

The third color filter CF3 may transmit green light that has passed through the second color conversion layer CCL2 and is incident thereon and absorb light of the remaining wavelengths, thereby increasing the purity of green light emitted to the outside of the display device.

At least two selected from the third color filter CF3, second color filter CF2, and first color filter CF1 may overlap each other in a plan view in the non-emission area NLA1 and serve as a light blocking layer.

The non-emission area NLA1 may overlap the pixel defining layer PDL of the display unit DC and the bank BK1 of the color conversion unit CC in a plan view.

A third insulating layer IL5 may be disposed between the color filters CF1, CF2, and CF3 and the display unit DC.

In an embodiment, for example, the third insulating layer IL5 may include an organic material or an inorganic material such as a silicon nitride (SiNₓ), a silicon oxide (SiOₓ), or a silicon oxynitride (SiOₓN_{y}).

A second insulating layer IL4 may be positioned between the third insulating layer IL5 and the display unit DC.

The second insulating layer IL4 may include, for example, a silicon nitride (SiNₓ), a silicon oxide (SiOₓ), or a silicon oxynitride (SiOₓN_{y}).

In another embodiment, the second insulating layer IL4 may be omitted.

The color conversion unit CC may include a bank BK1 disposed between the second insulating layer IL4 and the display unit DC.

The bank BK1 may define a first opening OP1, a second opening OP2, and a third opening OP3, each of which overlaps the pixel opening in a plan view.

The sizes of the first opening OP1, the second opening OP2, and the third opening OP3 may be different from each other or the same as each other.

The first color conversion layer CCL1 may be disposed within the first opening OP1 in a plan view.

The first color conversion layer CCL1 may convert supplied light into red.

The first color conversion layer CCL1 may include a first quantum dot QD1.

The second color conversion layer CCL2 may be disposed within the second opening OP2 in a plan view.

The second color conversion layer CCL2 may convert supplied light into green.

The second color conversion layer CCL2 may include second quantum dots QD2.

The quantum dots including the first quantum dot QD1 and the second quantum dot QD2 will be described in detail below.

In this specification, quantum dots (hereinafter also referred to as semiconductor nanocrystals) include group II-VI compounds, group III-V compounds, group IV-VI compounds, group IV elements or compounds, group I-III-VI compounds, and group II-III-VI compounds, group I-II-IV-VI compounds, or a combination thereof.

The II-VI group compounds include binary compounds selected from CdSe, CdTe, ZnS, ZnSe, ZnTe, ZnO, HgS, HgSe, HgTe, MgSe, MgS, and mixtures thereof; ternary compounds selected from AglnS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof, and tetraelement compounds selected from HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The Group II-VI compound may further include a Group III metal.

The III-V group compounds may be selected from binary compounds such as GaN, GaP, GaAs, GaSb, AlN, AIP, AIAs, AISb, InN, InP, InAs, InSb and their mixtures, ternary compounds selected from GaNP, GaNAs, GaNSb, GaPAs, GaPSb, AlNP, AlNAs, AlNSb, AIPAs, AIPSb, InGaP, InNP, InNAs, InNSb, InPAs, InZnP, InPSb, and their mixtures, and quaternary compounds selected from GaAINP, GaAINAs, GaAINSb, GaAIPAs, GaAIPSb, GalnNP, GalnNAs, GalnNSb, GalnPAs, GalnPSb, InAINP, InAINAs, InAINSb, InAIPAs, InAIPSb, InZnP, and their mixtures.

The group III-V compound may further include a group II metal (e.g., InZnP).

The IV-VI group compounds include binary compounds selected from SnS, SnSe, SnTe, PbS, PbSe, PbTe, and mixtures thereof, ternary compounds selected from SnSeS, SnSeTe, SnSTe, PbSeS, PbSeTe, PbSTe, SnPbS, SnPbSe, SnPbTe, and mixtures thereof, and quaternary element compounds selected from SnPbSSe, SnPbSeTe, SnPbSTe, and mixtures thereof.

The Group IV element or compound is a monoelement compound selected from the group consisting of Si, Ge, and combinations thereof, and a binary compound selected from SiC, SiGe, and combinations thereof, but is not limited thereto.

Examples of the Group I-III-VI compounds include, but are not limited to, CulnSe₂, CulnS₂, CulnGaSe, and CulnGaS.

Examples of the Group I-II-IV-VI compounds include, but are not limited to, CuZnSnSe and CuZnSnS.

The Group IV element or compound is a single element selected from the group consisting of Si, Ge, and mixtures thereof, and a binary compound selected from the group consisting of SiC, SiGe, and mixtures thereof.

The group II-III-VI compounds include ZnGaS, ZnAIS, ZnlnS, ZnGaSe, ZnAlSe, ZnInSe, ZnGaTe, ZnAlTe, ZnInTe, ZnGaO, ZnAIO, ZnlnO, HgGaS, HgAIS, HgInS, HgGaSe, HgAlSe, HgInSe, HgGaTe, HgAITe, HgInTe, MgGaS, MgAIS, MgInS, MgGaSe, MgAlSe, MgInSe, and combinations thereof, but are not limited thereto.

The group I-II-group IV-VI compound may be selected from CuZnSnSe and CuZnSnS, but is not limited thereto.

In an embodiment, the quantum dots may not include cadmium.

Quantum dots may include semiconductor nanocrystals based on group III-V compounds including indium and phosphorus.

The group III-V compound may further include zinc.

Quantum dots may include semiconductor nanocrystals based on II-VI compounds including chalcogen elements (e.g., sulfur, selenium, tellurium, or combinations thereof) and zinc.

In quantum dots, the above-mentioned binary element compound, ternary element compound, and/or quaternary compound may exist in a particle form at a uniform concentration, or may exist in a same particle with the concentration distribution partially divided into different states.

In an embodiment, one quantum dot may have a core/shell structure surrounding other quantum dots.

The interface between the core and the shell may have a concentration gradient in which the concentration of elements present in the shell decreases toward the center.

In some embodiments, quantum dots may have a core-shell structure including a core containing the above-described nanocrystals and a shell surrounding the core.

The shell of the quantum dot may serve as a protective layer to maintain semiconductor properties by preventing chemical denaturation of the core and/or as a charging layer to impart electrophoretic properties to the quantum dot.

The shell may have a single layer structure or a multilayer structure.

The interface between the core and the shell may have a concentration gradient in which the concentration of elements present in the shell decreases toward the center.

Examples of the shell of the quantum dot include metal or non-metal oxides, semiconductor compounds, or combinations thereof.

For example, the oxide of the metal or non-metal is a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, MgAl₂O₄, CoFe₂O₄, NiFe₂O₄, CoMn₂O₄, etc., but the invention is not limited thereto.

In addition, the semiconductor compounds include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AIP, AISb, etc. However, the invention is not limited thereto.

The interface between the core and the shell may have a concentration gradient in which the concentration of elements present in the shell decreases toward the center.

Additionally, the semiconductor nanocrystal may have a structure including a single semiconductor nanocrystal core and a multi-layered shell surrounding it.

In an embodiment, the multilayer shell may have two or more layers, such as 2, 3, 4, 5, or more layers.

The two adjacent layers of the shell may have a single composition or different compositions.

In a multilayer shell, each layer may have a composition that changes along the radius.

Quantum dots may have a full width of half maximum (FWHM) of the emission wavelength spectrum of about 45 nanometers (nm) or less, for example, about 40 nm or less, about 30 nm or less, and within this range, color purity or color reproducibility may be improved.

Additionally, since the light emitted through these quantum dots is emitted in all directions, the optical viewing angle may be improved.

The quantum dots may have different energy band gaps between the shell material and the core material.

For example, the energy band gap of the shell material may be larger than that of the core material.

In other embodiments, the energy band gap of the shell material may be less than that of the core material.

The quantum dots may have a multi-layered shell.

In a multilayer shell, the energy band gap of the outer layer may be greater than that of the inner layer (i.e., the layer close to the core).

In a multilayer shell, the energy band gap of the outer layer may be smaller than that of the inner layer.

Quantum dots may control absorption/emission wavelengths by adjusting their composition and size.

The maximum emission peak wavelength of the quantum dot may range from ultraviolet to infrared wavelengths or longer.

Quantum dots may have quantum efficiency of at least about 10%, such as at least about 30%, at least about 50%, at least about 60%, at least about 70%, at least about 90%, or even at least 100%.

Quantum dots may have a relatively narrow spectrum.

The quantum dots may have a full width at half maximum of the emission wavelength spectrum of, for example, about 50 nm or less, such as about 45 nm or less, about 40 nm or less, or about 30 nm or less.

The quantum dots may have a particle size of about 1 nm or greater and about 100 nm or less.

The size of a particle refers to the diameter of the particle or the diameter converted by assuming a spherical shape from a two-dimensional image obtained by transmission electron microscope analysis.

The quantum dots may have a size in a range of about 1 nm to about 20 nm, such as at least 2 nm, at least 3 nm, or at least 4 nm and at most 50 nm, at most 40 nm, at most 30 nm, at most 20 nm, at most 15 nm, such as at least 10 nm.

The shape of the quantum dot is not particularly limited.

For example, the shape of the quantum dot may include, but is not limited to, a sphere, polyhedron, pyramid, multipod, square, cuboid, nanotube, nanorod, nanowire, nanosheet, or a combination thereof.

Quantum dots are commercially available or may be appropriately synthesized.

The particle size of quantum dots may be controlled relatively freely during colloid synthesis, and the particle size may also be adjusted uniformly.

Quantum dots may include organic ligands (e.g., having hydrophobic and/or hydrophilic moieties).

The organic ligand residue may be bound to the surface of the quantum dot.

The organic ligand includes RCOOH, RNH2, R2NH, R3N, RSH, R3PO, R3P, ROH, RCOOR, RPO(OH)2, RHPOOH, R2POOH, or a combination thereof, where R is each independently C3 to substituted or unsubstituted alkyl of C40 (e.g., C5 or more and C24 or less), substituted or unsubstituted alkenyl, substituted or unsubstituted aliphatic hydrocarbon group of C3 to C40, substituted or unsubstituted aryl group of C6 to C40, a substituted or unsubstituted aromatic hydrocarbon group of C6 to C40 (e.g., C6 or more and C20 or less), or a combination thereof.

Examples of the organic ligand include thiol compounds such as methane thiol, ethane thiol, propane thiol, butane thiol, pentane thiol, hexane thiol, octane thiol, dodecane thiol, hexadecane thiol, octadecane thiol, and benzyl thiol; methane amine, ethane amine, propane amine, butane amine, pentyl amine, hexyl amine, octyl amine, nonyl amine, decyl amine, dodecyl amine, hexadecyl amine, octadecyl amine, dimethyl amine, diethyl amine, dipropyl amine tributylamine, trioctylamine, etc.; carboxylic acid compounds such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, and benzoic acid; phosphine compounds such as methyl phosphine, ethyl phosphine, propyl phosphine, butyl phosphine, pentyl phosphine, octyl phosphine, dioctyl phosphine, tributyl phosphine, trioctyl phosphine, etc.; phosphines such as methyl phosphine oxide, ethyl phosphine oxide, propyl phosphine oxide, butyl phosphine oxide, pentyl phosphine oxide, tributyl phosphine oxide, octyl phosphine oxide, dioctyl phosphine oxide, and trioctyl phosphine oxide compounds or their oxide compounds; diphenyl phosphine, triphenyl phosphine compounds, or their oxide compounds; C5 to C20 alkyl phosphinic acids, C5 to C20 alkyl phosphonic acids such as hexylphosphinic acid, octylphosphinic acid, dodecanephosphinic acid, tetradecanephosphinic acid, hexadecanephosphinic acid, and octadecanephosphinic acid.

Quantum dots may include hydrophobic organic ligands alone or in a mixture of one or more types.

The hydrophobic organic ligand may not contain a photopolymerizable residue (e.g., an acrylate group, a methacrylate group, etc.).

According to an embodiment, the transmission layer TL may be disposed in the third opening OP3.

The transmission layer TL may be disposed in a portion corresponding to the blue light emission area BLA in a space partitioned by the bank BK1. The transmission layer TL may be disposed in a same layer as the first color conversion layer CCL1 and the second color conversion layer CCL2.

The transmission layer TL may transmit light incident from the light emitting element ED as it is or without substantially converting the wavelength thereof.

The transmission layer TL may include the first scatterer SC1.

The transmission layer TL may include a polymer resin and a first scatterer SC1 included in the polymer resin.

The first scatterer SC1 may include at least one selected from SiO₂, BaSO₄, Al₂O₃, ZnO, ZrO₂, and TiO₂.

In an embodiment, for example, the first scatterer SC1 may include TiO₂, but is not limited thereto.

The first color conversion layer CCL1 may include a first scatterer SC1.

The first color conversion layer CCL1 may include a same type of first scatterer SC1 as the transmission layer TL.

The second color conversion layer CCL2 according to an embodiment may include a first sub-region CCL2a and a second sub-region CCL2b.

The first sub-region CCL2a may be disposed adjacent to the bank BK1.

The first sub-region CCL2a may be in contact with the bank BK1 and may have a shape surrounding an inner surface of the bank BK1 defining the second opening OP2.

The first sub-region CCL2a may be spaced apart from a center of the second opening OP2 in a plan view.

The first sub-region CCL2a may not cover the center portion of the second opening OP2 in a plan view.

The second sub-region CCL2b may be positioned to overlap the center of the second opening OP2 in a plan view.

The first sub-region CCL2a may be disposed between the second sub-region CCL2b and the bank BK1 in a plan view.

The first sub-region CCL2a may be formed through an inkjet process.

The first sub-region CCL2a may have a shape inclined toward the second insulating layer IL4.

The first sub-region CCL2a and the second sub-region CCL2b may form a single flat upper surface (for example, a surface facing the display part DC), but are not limited to this, and the surfaces of the first region CCL2a and the second region CCL2b may also form a step.

The first sub-region CCL2a may include the first scatterer SC1.

The first sub-region CCL2a may include a first scatterer SC1 of a same type as the first color conversion layer CCL1 and the transmission layer TL.

The first sub-region CCL2a does not include quantum dots.

The second sub-region CCL2b may include a second scatterer SC2 and a second quantum dot QD2.

The second scatterer SC2 may be a different type of scatterer than the first scatterer SC1.

Each of the first scatterer SC1 and the second scatterer SC2 may have a diameter in a range of about 20 nm to about 500 nm.

In an embodiment, referring to FIG. 4, the first scatterer SC1 may be TiO₂, and in particular, the first scatterer SC1 may be rutile.

The second scatterer SC2 may be TiO₂, and in particular, the second scatterer SC2 may be anatase.

Rutile and anatase are composed of a same type of atoms as shown in FIG. 4, and their crystal structures may be different from each other.

Accordingly, the physical properties of rutile and anatase may be different from each other.

According to an embodiment, the first scatterer SC1 with a rutile crystal structure may have high scattering characteristics of incident light.

The second scatterer SC2 having an anatase crystal structure may have a characteristic of increasing light transmittance while having a low characteristic of reflecting incident light.

Referring to FIG. 5, the green light LG1 incident on the second color conversion layer CCL2 in the front direction may be emitted through the second sub-region CCL2b including the second scatterer SC2 with high light transmittance EG2.

Blue light LB1 incident on the second color conversion layer CCL2 in the front direction may be converted into green light by the second quantum dot QD2 and emitted EG1.

In such an embodiment, a large amount of green light emitted from the light emitting element ED may be emitted in a direction in at and near 60 degrees as a side light LG2.

This side light LG2 may be incident toward the bank BK1.

The side light LG2 may be scattered in the first sub-region CCL2a including the first scatterer SC1 having high scattering characteristics and may be emitted to the outside of the display panel EG3.

According to an embodiment, the amount of green light emitted from the front of the display device may be improved.

Referring to FIG. 6, the first sub-region CCL2a is formed within the second opening OP2.

The first sub-region CCL2a may include a same material as the transmission layer TL.

The first sub-region CCL2a and the transmission layer TL may include a same first scatterer SC1.

According to an embodiment, the first sub-region CCL2a and the transmission layer TL may be formed using a same inkjet head.

Thereafter, as shown in FIG. 7, a second sub-region CCL2b is formed in the remaining portion of the second opening OP2 exposed by the first sub-region CCL2a.

The second sub-region CCL2b may include a second quantum dot QD2 and a second scatterer SC2.

The second sub-region CCL2b may be formed using an inkjet head different from the inkjet head for forming the first sub-region CCL2a.

In this specification, it is shown that the first sub-region CCL2a and the second sub-region CCL2b form a same upper surface, but the invention is not limited thereto, and the first sub-region CCL2a and the second sub-region CCL2b are may form an upper surface having a step.

Referring back to FIG. 3, the first insulating layer IL3 is disposed between the bank BK1, the first color conversion layer CCL1, the second color conversion layer CCL2, the transmission layer TL, and the display unit DC.

The first insulating layer IL3 may have a shape that covers the bank BK1, the first color conversion layer CCL1, the second color conversion layer CCL2, and the transmission layer TL.

The first insulating layer IL3 may include an inorganic material.

A filling layer FL may be positioned between the first insulating layer IL3 and the display unit DC.

The color conversion unit CC and the display unit DC may be combined by filling the space between the color conversion unit CC and the display unit DC with the filling layer FL.

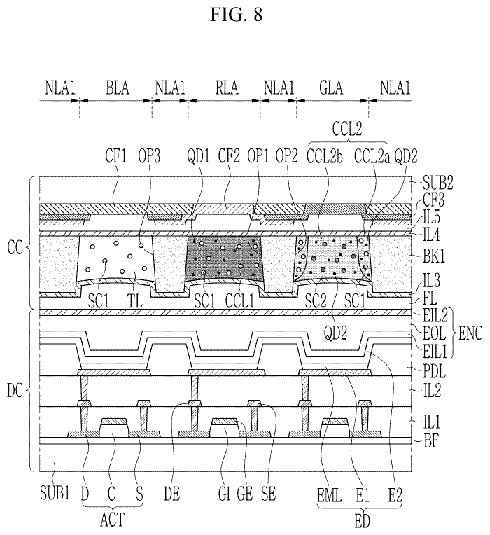

Hereinafter, a display panel according to other embodiments will be described with reference to FIGS. 8 to 10.

FIGS. 8, 9, and 10 are cross-sectional views of a display panel according to other embodiments.

The same or like elements shown in FIGS. 8, 9, and 10 have been labeled with the same reference characters as used above to describe the embodiment of the display panel shown in FIG. 3, and any repetitive detailed description thereof will hereinafter be omitted or simplified.

in an embodiment, referring to FIG. 8, the second color conversion layer CCL2 includes a first sub-region CCL2a and a second sub-region CCL2b.

The first sub-region CCL2a may be in contact with the bank BK1 and may have a shape surrounding the bank BK1 in a plan view.

The second sub-region CCL2b may be positioned to overlap the center of the second opening OP2 in a plan view.

The first sub-region CCL2a may be disposed between the second sub-region CCL2b and the bank BK1 in a plan view.

The first sub-region CCL2a may include a second quantum dot QD2 and a first scatterer SC1.

The first sub-region CCL2a may include a first scatterer SC1 of the same type as the first color conversion layer CCL1 and the transmission layer TL.

The second sub-region CCL2b may include a second quantum dot QD2 and a second scatterer SC2.

The second scatterer SC2 may be a different type of scatterer than the first scatterer SC1.

In such an embodiment, the first scatterer SC1 may be TiO₂ with a rutile crystal structure, and the second scatterer SC2 may be TiO₂ with an anatase crystal structure.

As shown in FIG. 4, rutile and anatase are composed of the same atoms, but have different crystal structures, and thus their physical properties may be different.

The first scatterer SC1 with a rutile crystal structure may have high scattering characteristics of incident light.

The second scatterer SC2 having an anatase crystal structure may have a characteristic of increasing light transmittance while having a low characteristic of reflecting incident light.

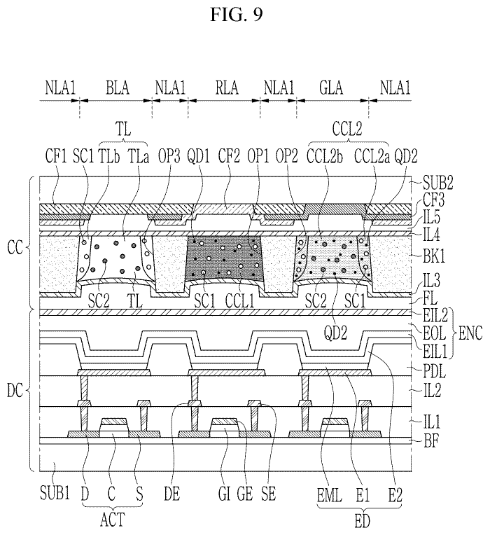

In another embodiment, referring to FIG. 9, the transmission layer TL may include a third sub-region TLa and a fourth sub-region TLb.

The third sub-region TLa may be in contact with the bank BK1 and may have a shape surrounding the bank BK1 in a plan view.

The fourth sub-region TLb may be positioned to overlap the center of the third opening OP3 in a plan view.

The third sub-region TLa may be disposed between the fourth sub-region TLb and the bank BK1 in a plan view.

The third sub-region TLa may include the first scatterer SC1.

The third sub-region TLa may include the same type of first scatterer SC1 as the first sub-region CCL2a and the first color conversion layer CCL1.

The fourth sub-region TLb may include the second scatterer SC2.

The fourth sub-region TLb may include the same type of second scatterer SC2 as the second sub-region CCL2b.

The first scatterer SC1 may be TiO₂ with a rutile crystal structure, and the second scatterer SC2 may be TiO₂ with an anatase crystal structure.

Among the light incident on the transmission layer TL, the light incident laterally toward the bank BK1 may be scattered by the first scatterer SC1 included in the third sub-region TLa and be emitted frontally.

Additionally, light incident toward the center of the transmission layer TL may be transmitted through the second scatterer SC2 included in the fourth sub-region TLb and be emitted to the front.

In the transmission layer TL according to an embodiment, the front light efficiency may be increased.

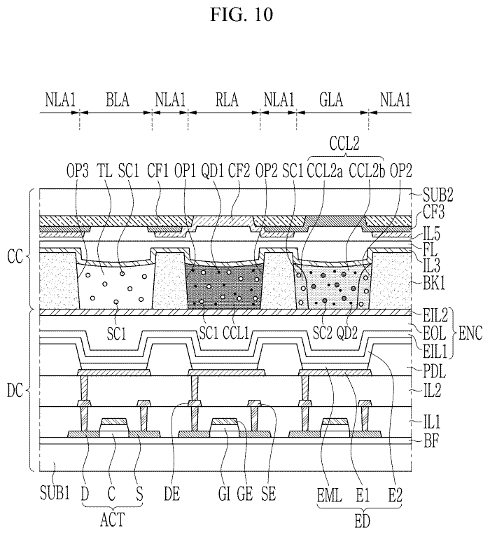

Next, referring to FIG. 10, the structure of the display unit DC according to another embodiment may be the same as the stacked structure of the display unit DC described with reference to FIG. 3.

Any repetitive detailed description of the same or like components as those described above will be omitted.

The color conversion unit CC is disposed on the encapsulation layer ENC.

The color conversion unit CC includes a second substrate SUB2 that overlaps or is disposed opposite to the first substrate SUB1.

The second substrate SUB2 may include a flexible material such as plastic that may be bent, folded, or rolled easily.

The color conversion unit CC may include a bank BK1 disposed on the encapsulation layer ENC.

The bank BK1 may include a first opening OP1, a second opening OP2, and a third opening OP3, each of which overlaps the pixel opening in a plan view.

The sizes of the first opening OP1, the second opening OP2, and the third opening OP3 may be different from each other or the same as each other.

The first color conversion layer CCL1 may be disposed within the first opening OP1.

The first color conversion layer CCL1 may convert supplied light into red.

The first color conversion layer CCL1 may include a first quantum dot QD1.

The second color conversion layer CCL2 may be disposed within the second opening OP2.

The second color conversion layer CCL2 may convert supplied light into green.

The second color conversion layer CCL2 may include second quantum dots QD2.

The transmission layer TL may be disposed within the third opening OP3.

The transmission layer TL may be disposed in the part corresponding to the blue light emission area BLA among the spaces partitioned by the barrier wall BK1.

The first color conversion layer CCL1 converts the incident light into red and emits the red light.

Additionally, the second color conversion layer CCL2 converts the incident light into green and emits the green light.

However, the light incident on the transmission layer TL is transmitted without color conversion.

The incident light may include blue light.

The incident light may be blue light alone or a mixture of blue light and green light.

Alternatively, the incident light may include all of blue light, green light, and red light.

The transmission layer TL may include the first scatterer SC1.

The transmission layer TL may include a polymer resin and a first scatterer SC1 included in the polymer resin.

The first scatterer SC1 may include at least one selected from SiO₂, BaSO₄, Al₂O₃, ZnO, ZrO₂, and TiO₂.

In an embodiment, for example, the first scatterer SC1 may include TiO₂, but is not limited thereto.

The transmission layer TL may transmit light incident from the light emitting element ED.

The first color conversion layer CCL1 may include a first scatterer SC1.

The first color conversion layer CCL1 may include the same type of first scatterer SC1 as the transmission layer TL.

The second color conversion layer CCL2 according to an embodiment may include a first sub-region CCL2a and a second sub-region CCL2b.

The first sub-region CCL2a may be in contact with the bank BK1 and may have a shape surrounding the bank BK1 in a plan view.

The second sub-region CCL2b may be positioned to overlap the center of the second opening OP2 in a plan view.

The first sub-region CCL2a may be disposed between the second sub-region CCL2b and the bank BK1 in a plan view.

The first sub-region CCL2a may be formed through an inkjet process.

The first sub-region CCL2a may have a shape inclined toward the encapsulation layer ENC.

The first sub-region CCL2a and the second sub-region CCL2b may form a flat upper surface (a surface facing the color filter CF), but are not limited to this, and the surfaces of the first sub-region CCL2a and the second sub-region CCL2b may also form a step or a curve.

The first sub-region CCL2a may include the first scatterer SC1.

The first sub-region CCL2a may include a first scatterer SC1 of the same type as the first color conversion layer CCL1 and the transmission layer TL.

Depending on the embodiment, the first sub-region CCL2a may not include quantum dots.

The second sub-region CCL2b may include a second quantum dot QD2 and a second scatterer SC2.

The second scatterer SC2 may be a different type of scatterer than the first scatterer SC1.

The first scatterer SC1 may be TiO₂ and, in particular, may have a rutile crystal structure.

The second scatterer SC2 may be TiO₂ and, in particular, may have an anatase crystal structure.

As shown in FIG. 4, rutile and anatase have different crystal structures from each other, and thus their physical properties may be different from each other.

According to an embodiment, the first scatterer SC1 with a rutile crystal structure may have high scattering characteristics of incident light.

The second scatterer SC2 having an anatase crystal structure may have a characteristic of increasing light transmittance while having a low characteristic of reflecting incident light.

Accordingly, the emission efficiency of green light incident on the second color conversion layer CCL2 may be improved.

A first insulating layer IL3, a filling layer FL, and a third insulating layer IL5 on the bank BK1, the first color conversion layer CCL1, the second color conversion layer CCL2, and the transmission layer TL may be disposed sequentially.

The first insulating layer IL3 may have a shape that covers the bank BK1, the first color conversion layer CCL1, the second color conversion layer CCL2, and the transmission layer TL.

Each of the first insulating layer IL3, the filling layer FL, and the third insulating layer IL5 may have a shape that overlaps the entire surface of the second substrate SUB2.

Each of the first insulation layer IL3, the filling layer FL, and the third insulation layer IL5 may include an organic insulating material or an inorganic insulating material, and the inorganic insulating material may include at least one selected from a silicon nitride, a silicon oxide, and a silicon oxynitride.

According to an embodiment, at least one selected from the first insulating layer IL3 and the third insulating layer IL5 may be omitted.

The color conversion unit CC includes a first color filter CF1, a second color filter CF2, and a third color filter CF3 disposed between the second substrate SUB2 and the display unit DC.

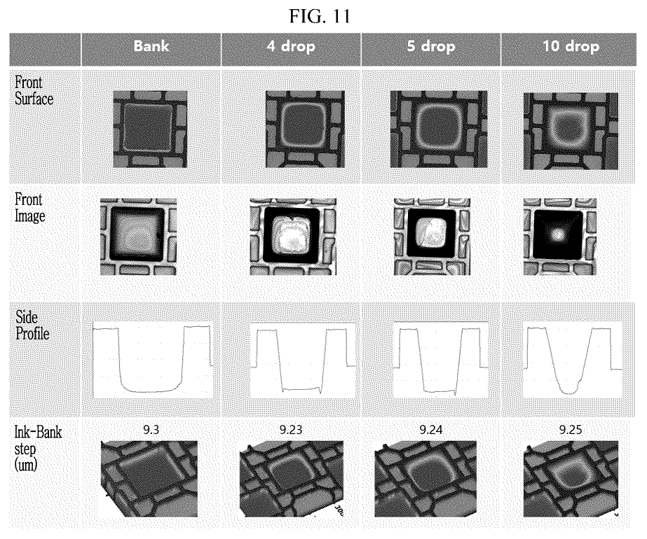

Hereinafter, the second color conversion layer according to an embodiment will be described with reference to FIG. 11.

FIG. 11 is an image of a second color conversion layer according to an inkjet process according to an embodiment.

FIG. 11 is an image examining whether a first sub-region is formed according to the amount of drops ejected from the inkjet head when an inkjet process is performed in the opening of the bank (Bank).

Referring to FIG. 11, it was confirmed that when about 4 to 5 drops were discharged, a first sub-region of an appropriate shape was formed.

In the case of 10 drops, the area occupied by the first sub-region increases, so the front light efficiency may decrease.

The second color conversion layer according to an embodiment may include first and second sub-regions including different types of scatterers.

According to embodiments, the front luminance may be increased by emitting green light incident from the side to the front.

In such embodiments, the reflectance of light emitted from the light emitting element may be reduced.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device, comprising:
a first substrate;
a transistor disposed on the first substrate;
a light emitting element electrically connected to the transistor; and
a bank disposed on the light emitting element, wherein an opening is defined through the bank, and
a color conversion layer disposed within the opening, wherein the color conversion layer comprises quantum dots,
wherein the color conversion layer includes:
a first sub-region adjacent to the bank and including a first scatterer; and
a second sub-region overlapping a center of the color conversion layer in a plan view and including a second scatterer,
where one of the first scatterer and the second scatterer is rutile, and the other of the first scatterer and the second scatterer is anatase.

2. The display device of claim 1, wherein
the first scatterer is rutile, and
the second scatterer is anatase.

3. The display device of claim 1, wherein
the first sub-region does includes no quantum dot, and
the second sub-region includes the quantum dots.

4. The display device of claim 1, further comprising
a transmission layer disposed within another opening defined through the bank,
wherein the transmission layer includes the first scatterer.

5. The display device of claim 4, wherein
the color conversion layer is a second color conversion layer,
the display device further includes a first color conversion layer disposed within another opening defined through the bank, and
the first color conversion layer includes the first scatterer.

6. The display device of claim 1, wherein
the first sub-region is disposed between the second sub-region and the bank in the plan view.

7. The display device of claim 1, wherein
the light emitting element emits light which is a mixture of green light and blue light.

8. The display device of claim 1, wherein
each of the first scatterers and the second scatterers has a diameter in a range of about 20 nanometers to about 500 nanometers.

9. The display device of claim 1, wherein
each of the first sub-region and the second sub-region includes the quantum dots.

10. The display device of claim 4, wherein
the transmission layer includes:
a third sub-region including the first scatterer; and
a fourth sub-region including the second scatterer.

11. The display device of claim 1, further comprising:
an encapsulation layer disposed on the light emitting element;
a second substrate disposed opposite to the first substrate;
a color filter disposed between the second substrate and the encapsulation layer; and
a filling layer disposed between the color filter and the encapsulation layer, and
the bank and the color conversion layer are positioned between the color filter and the filling layer.

12. The display device of claim 1, further comprising:
an encapsulation layer disposed on the light emitting element;
a second substrate disposed opposite to the first substrate;
a color filter disposed between the second substrate and the encapsulation layer; and
a filling layer disposed between the color filter and the encapsulation layer, and
the bank and the color conversion layer are positioned between the encapsulation layer and the filling layer.

13. A display device, comprising:
a first substrate;
a transistor disposed on the first substrate,
a light emitting element electrically connected to the transistor;
a bank disposed on the light emitting element, wherein an opening is defined through the bank; and
a color conversion layer disposed within the opening, wherein the color conversion layer comprises quantum dots, and
the color conversion layer includes:
a first sub-region adjacent to the bank and including a first scatterer; and
a second sub-region overlapping a center of the color conversion layer in a plan view and including a second scatterer,
where the first scatterer and the second scatterer are composed of a same type of atoms and have different crystal structures from each other.

14. The display device of claim 13, wherein
each of the first scatterer and the second scatterer is TiO₂.

15. The display device of claim 13, wherein
one of the first scatterer and the second scatterer is rutile, and
the other of the first scatterer and the second scatterer is anatase.

16. The display device of claim 15, wherein
the first scatterer is rutile, and
the second scatterer is anatase.

17. The display device of claim 13, wherein
the first sub-region does includes no quantum dot, and
the second sub-region includes the quantum dots.

18. The display device of claim 13, further comprising
a transmission layer disposed within another opening defined through the bank,
wherein the transmission layer includes the first scatterer.

19. The display device of claim 18, wherein
the color conversion layer is a second color conversion layer,
the display device further comprises a first color conversion layer disposed within another opening defined through the bank, and
wherein the first color conversion layer includes the first scatterer.

20. The display device of claim 13, wherein
the light emitting element emits light which is a mixture of green light and blue light.
